(19) United States
(12) Patent Application Publication
(10) Pub. No.: US 2025/0277864 A1
(43) Pub. Date: Sep. 4, 2025

(54) METHOD FOR PROVIDING A CELL IMPEDANCE MODEL TO A BATTERY CELL

(71) Applicant: Robert Bosch GmbH, Stuttgart (DE)

(72) Inventor: Ingo Priemer, Stuttgart (DE)

(21) Appl. No.: 19/066,511

(22) Filed: Feb. 28, 2025

(30) Foreign Application Priority Data
Mar. 1, 2024 (DE) 10 2024 201 951.8

(51) Int. Cl. G01R 31/389; G01R 31/367; G01R 31/374; G01R 31/3842

(52) U.S. Cl. CPC G01R 31/389; G01R 31/367; G01R 31/374; G01R 31/3842

(57) ABSTRACT

A computer-implemented method for providing a cell impedance model for a battery cell by providing the cell impedance model with a low frequency component of as an Oustaloup approximation of a substantially linear low frequency component of a Nyquist relationship, measuring (S1) the battery cell at different operating points and at different frequencies to obtain measurement series with a terminal voltage, wherein the operating points are determined at least by the cell current and/or charging state; and configuring (S2) and providing (S3) the cell impedance model with the measurement series by minimizing a difference between the measured and modeled terminal voltage, wherein the exponent value is configured using an exponent function depending on the respective operating point.

### BACKGROUND

The invention relates to battery cells, and in particular to methods for modeling cell impedance using a cell impedance model. The invention further relates to ways of modeling diffusion effects with a cell impedance model.

The electrical behavior of battery cells of device batteries is often modeled using a so-called cell impedance model. The cell impedance model is based on an equivalent circuit diagram of the battery cell having an ohmic resistance for representing high frequency effects and having a series of RC elements for representing low frequency effects, such as diffusion effects.

The low-frequency component of the cell impedance is usually determined in the model range (Laplace or frequency range) as follows:

$${R}_{D} ( s ) {( \frac{s + {ω}_{h}}{s + {ω}_{l}} )}^{η}$$

wherein the exponent represents η the slope of the imaginary portion of the cell impedance divided by the real portion of the cell impedance, and wherein s is the Laplace variable.

Such modeling is useful because the straight lines on a graphical representation of the low frequency component of the Nyquist plot of a real battery cell slope downward as frequency rises. This straight line is modeled using an Oustaloup recursive approximation between an upper and lower boundary frequency. To account for temperature dependencies, the exponent may be modeled η depending on temperature.

### SUMMARY

According to the invention, a method for providing a cell resistance model for a battery cell of a device battery according to the disclosure as well as a corresponding device are provided.

According to a first aspect, a method is provided for providing a cell impedance model for a battery cell of a device battery, comprising the steps of:
providing the cell impedance model with a low frequency component of

$${R}_{D} ( s ) {( \frac{s + {ω}_{h}}{s + {ω}_{l}} )}^{η ( T , I , SOC )}$$

as an Oustaloup approximation of a substantially linear low-frequency part of the Nyquist relationship, wherein the exponent represents η the slope of an imaginary portion of the cell impedance over a real portion of the cell impedance, wherein ωₕ, ωₗ corresponds to a predetermined upper and lower frequency of the low-frequency range of the Nyquist relationship, I corresponds to the cell current, T corresponds to a cell temperature and SOC corresponds to a charging state of the battery variable state, and whereby the Laplace variable is s;

measuring the battery cell at different operating points to obtain measurement series having a terminal voltage, wherein the operating points are determined at least by the cell current and/or charging state;

configuring and providing the cell impedance model with the measurement series by minimizing a difference between the measured and modeled clamping voltage, wherein the exponent η is configured depending on the respective operating point.

The operating point may furthermore be determined by a cell temperature.

As described above, the equivalent circuit model for a battery cell comprises a series of RC elements for modeling the low frequency behavior of a battery cell, which are in particular caused by diffusion effects.

These can be described mathematically by the term

$${R}_{D} ( s ) ( 1 + \frac{{K}_{1}}{{τ}_{1} s + 1} + \frac{{K}_{2}}{{τ}_{2} s + 1} + … + \frac{{K}_{N}}{{τ}_{N} s + 1} )$$

with K and τ representing a constant and time constant of a respective RC element.

It may be contemplated that the Oustaloup approximation of the series of RC elements has the form:

$${R}_{D} ( s ) {( \frac{s + {ω}_{h}}{s + {ω}_{l}} )}^{η}$$

wherein ωₕ, ωₗ corresponds to a predetermined upper and lower frequency of the low frequency range of the Nyquist relationship and η corresponds to the operating point-dependent exponent value.

Because Nyquist plots for the low-frequency range provide a straight Nyquist curve, it may be represented using a Nyquist term corresponding to an Oustaloup approximation.

The Nyquist term has an exponent η that indicates the slope of the straight line of the Nyquist curve in the low-frequency range. Thus, modeling the cell impedance model using the Oustaloup recursive approximation method in the low frequency range is particularly suitable for modeling diffusion effects.

In general, an Oustaloup approximation is a method of recursive approximation of fractional (non-integer) derivatives and integrals. This expands the classical concept of differentiation and integration to non-integer orders, allowing for more accurate modeling of physical and technical processes over a wider range of frequencies. The Oustaloup approximation utilizes a network of resistors and capacitors (in the case of analog implementations) or a digital filter structure (for digital implementations) to approximate a fractional derivative or integration over a specific frequency range.

In particular, the cell impedance of a battery cell is not linearly dependent on the operating point. In particular, it has been observed that even in the low-frequency region of the Nyquist curve, there is a considerable dependence of the slope of the straight line on the operating point, in particular on a cell current and a cell temperature. The above method for providing a cell impedance model thus provides for modelling the exponent of the Nyquist term depending on an operating point of the battery cell, in particular depending on a cell current and/or a charging state of the cell, namely as η(I, SOC).

Thus, by configuring the model parameters when providing a cell impedance model, additional model parameters result which can be used to indicate the dependence of the exponent of i the Nyquist term depending on a cell current and/or a charging state of the battery cell. In particular, the exponent of the Nyquist term may be determined by configuring a predetermined functional equation, which may be predetermined as a second or higher order polynomial function, for example. Also, the exponent may be modeled using a data-based model, in particular a Gaussian-process model, in which a cell current and/or charging state, and in particular a cell temperature, is mapped to the exponent value.

The configuration is based on measurement series which indicate time series of a measured terminal voltage, the cell current, the charging state and, if applicable, the cell temperature of a battery cell at different operating points. The time series must include different frequency components (in particular components between the upper and lower frequency). By an iterative method, the differences between the measured terminal voltage and the terminal voltage determined based on the modeled cell impedance may then be minimized. The operating point-dependent parameter is thus η(T, I, SOC) configured instead of the R_{X}C_{X} elements of the RC elements or the K_{X} and τ_{X} values of the RC equivalent circuit diagram.

### BRIEF DESCRIPTION OF THE DRAWINGS

Embodiments are explained in more detail below with reference to the accompanying drawings. Shown are:

FIG. 1 is a schematic illustration of an equivalent circuit diagram model based on which a cell impedance model for calculating a cell impedance is modeled;

FIG. 2 is a path of an exemplary Nyquist curve for a battery cell;

FIG. 3 is a dependence of the exponent value of the low frequency portion of the Nyquist curve on the cell temperature and on the cell current;

FIG. 4 is a flow chart for configuring a cell impedance model based on modeling diffusion effects using the Oustaloup recursive approximation method.

### DETAILED DESCRIPTION

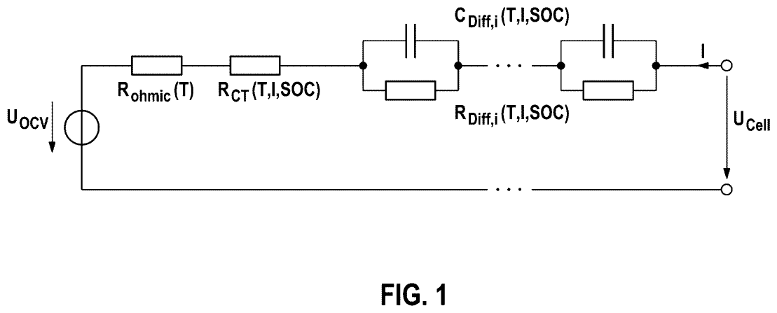

FIG. 1 schematically shows an equivalent circuit diagram 1 for a battery cell corresponding to an equivalent circuit diagram model. The equivalent circuit diagram model comprises an ohmic internal resistance R_{ohmic}(T) which is temperature-dependent, a serial resistance R_{CT}(T, I, SOC) dependent on a temperature T, a battery current I and a charging state SOC, and an open-circuit voltage source U_{OCV}. To illustrate the diffusion behavior, one or more RC elements with component values R_{Diff,i}(T,I,SOC) and C_{Diff,i}(T,I,SOC) are provided in series for this purpose, with which different time constants τ₁, τ₂, . . . , τᵢ of the battery cell behavior can be represented.

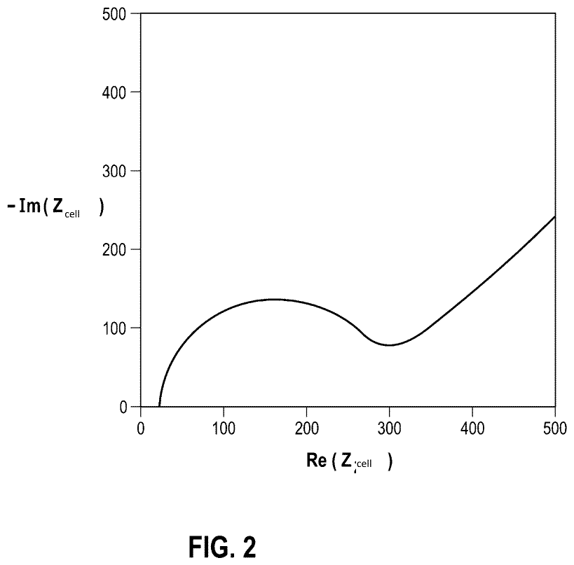

FIG. 2 shows a Nyquist curve that can be obtained by measuring such a battery cell at multiple operating points. The Nyquist curve shows a relationship between an imaginary portion and a real portion of a cell impedance at different frequencies.

The operating point is indicated by a battery current, by a charging state and, if applicable, by a temperature at a particular frequency. For a range of lower frequencies in particular, this Nyquist curve runs linearly with a slope (right portion) which is dependent on the operating point.

Modeling using the Oustaloup recursive approximation method makes use of this linear behavior and calculates the parameter values in the equivalent circuit diagram according to the number N of RC members, using the term

$${R}_{D} ( s ) ( 1 + \frac{{K}_{1}}{{τ}_{1} s + 1} + \frac{{K}_{2}}{{τ}_{2} s + 1} + … + \frac{{K}_{N}}{{τ}_{N} s + 1} ) ⇔ {R}_{D} ( s ) {( \frac{s + {ω}_{h}}{s + {ω}_{l}} )}^{η}$$

so that the following mathematical model is obtained as the cell impedance model.

$${Z}_{Zelle} = {R}_{ohmic} ( T ) + {R}_{C T} ( T , I , SOC ) + {R}_{D} ( s ) {( \frac{s + {ω}_{h}}{s + {ω}_{l}} )}^{η}$$

Wherein ωₕ, ωₗ corresponds to the upper and lower frequency of the linear area of the Nyquist curve.

The slope is then indicated by the exponent value η.

It has been observed that the slope of the Nyquist curve in the low frequency portion depends not only on the temperature but also on the operating point of the battery cell.

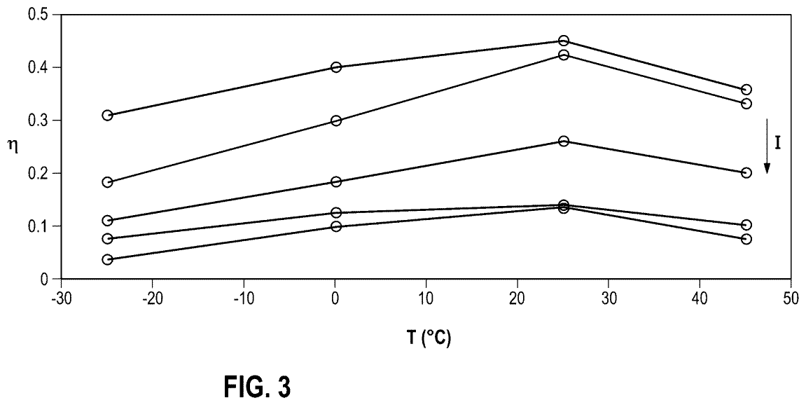

To illustrate this, the dependence of the exponent value η on the cell temperature T and on the cell current I is shown as an example in FIG. 3. The higher the cell current I, the lower the slope of the Nyquist curve in the low-frequency range.

According to a cell impedance model, it is therefore provided to use the charging state SOC, the cell current I and the temperature T not only for determining the series resistance R_{CT}, but also for adjusting the exponential value η(T, I, SOC) of the Nyquist term for the Oustaloup recursive approximation method. This allows the cell impedance to be modeled more accurately:

$${Z}_{Zelle} = {R}_{ohmic} ( T ) + {R}_{C T} ( T , I , SOC ) + {R}_{D} ( s ) {( \frac{s + {ω}_{h}}{s + {ω}_{l}} )}^{η ( T , I , SOC )}$$

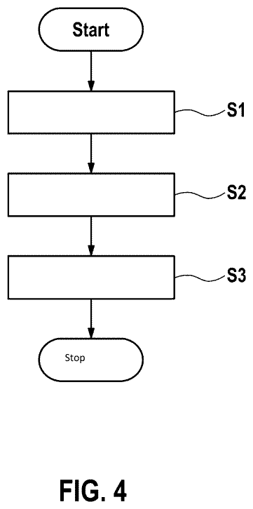

A corresponding method to create such a cell impedance model is described using the flow chart in FIG. 4.

For this purpose, in step S1, the battery cell is measured at different operating points using measurement series. The measurement series may indicate time series for a measured terminal voltage at various operating points, i.e., the cell current, charging state, and, if applicable, the cell temperature of the battery cell. The time series should include different frequency components (in particular components between the upper and lower frequency).

In step S2, during an iterative configuration method for an operating point of a cell current, a cell temperature and a charging state, the slope of the Nyquist curve corresponding to the exponential value of the Oustaloup term is determined (by observation at different frequencies within the frequency range). This exponential value can be configured for the measured operating points using a predetermined exponential function to determine the exponential value, e.g. a polynomial function.

Thus, the parameters can be obtained η(T, I, SOC) by optimization with the different measurement series. Further, the parameter may be determined in R_{D}(s) parallel to the exponent function by a corresponding iterative method.

In step S3, the cell impedance model is provided for use in simulations, in a battery management system (BMS), or in a digital twin. The cell impedance model may further be used in a battery management system (BMS) for predicting the power/energy/current still available.

Furthermore, the cell impedance model may be used in the battery management system as a reference model for determining the state of health resistance (SOHR), or essentially the increase in cell impedance due to aging or production tolerances.

1. A computer-implemented method for providing a cell impedance model for a battery cell of a device battery, the method comprising:
providing the cell impedance model with a low frequency component of
$${R}_{D} ( s ) {( \frac{s + {ω}_{h}}{s + {ω}_{l}} )}^{η ( I , SOC )}$$
as an Oustaloup approximation of a substantially linear low frequency component of a Nyquist relationship, wherein the exponent value η represents the slope of an imaginary part of the cell impedance over a real part of the cell impedance, wherein ωₕ, ωₗ corresponds to a predetermined upper or lower frequency of the low frequency range of the Nyquist relationship, wherein I corresponds to a supplied cell current and SOC corresponds to a predetermined charging state of the battery cell and R_{□}(s) corresponds to an impedance parameter, and wherein s is the Laplace variable;
measuring, via a computer, (S1) the battery cell at different operating points and at different frequencies to obtain measurement series with a terminal voltage, wherein the operating points are determined at least by the cell current and/or charging state;
configuring (S2) and providing (S3), via the computer the cell impedance model with the measurement series by minimizing a difference between the measured and modeled terminal voltage, wherein the exponent value η is configured using an exponent function depending on the respective operating point.

2. The method according to claim 1, wherein the operating point is further determined by a cell temperature (T).

3. The method according to claim 1, wherein an exponent value is determined for each of multiple operating points in order to configure the cell impedance model for configuring the exponent function, and the exponent function is indicated by a data-based or parametric model.

4. The method according to claim 3, wherein the exponential function is predetermined by a polynomial function.

5. A battery management system configured to determine a charging state by modeling a terminal voltage and comprising a cell impedance model for a battery cell of a device battery,
wherein the cell impedance model includes a low frequency component of
as an Oustaloup approximation of a substantially linear low frequency component of a Nyquist relationship, wherein the exponent value represents the slope of an imaginary part of the cell impedance over a real part of the cell impedance, wherein correspond to a predetermined upper or lower frequency of the low frequency range of the Nyquist relationship, wherein I corresponds to a supplied cell current and SOC corresponds to a predetermined charging state of the battery cell and corresponds to an impedance parameter, and wherein s is a Laplace variable;
wherein the cell impedance model is provided with a measurement series of a terminal voltage, wherein the measurement series includes measurements of the battery cell at different operating points and at different frequencies, wherein the operating points are determined at least by the cell current and/or charging state; and
wherein the cell impedance model is configured with the measurement series by minimizing a difference between the measured and modeled terminal voltage, wherein the exponent value is configured using an exponent function depending on the respective operating point.

6. A non-transitory, machine-readable storage medium comprising instructions that, when executed by computer, prompt the computer to
provide the cell impedance model with a low frequency component of
as an Oustaloup approximation of a substantially linear low frequency component of a Nyquist relationship, wherein the exponent value represents the slope of an imaginary part of the cell impedance over a real part of the cell impedance, wherein correspond to a predetermined upper or lower frequency of the low frequency range of the Nyquist relationship, wherein I corresponds to a supplied cell current and SOC corresponds to a predetermined charging state of the battery cell and corresponds to an impedance parameter, and wherein s is the Laplace variable;
measure (S1) the battery cell at different operating points and at different frequencies to obtain measurement series with a terminal voltage, wherein the operating points are determined at least by the cell current and/or charging state;
configure (S2) and provide (S3) the cell impedance model with the measurement series by minimizing a difference between the measured and modeled terminal voltage, wherein the exponent value is configured using an exponent function depending on the respective operating point.
